(19) United States
(12) Patent Application Publication
(10) Pub. No.: US 2025/0105036 A1
(43) Pub. Date: Mar. 27, 2025

(54) WET PROCESSING WITH AUTOMATIC PROCESS CONTROL

(71) Applicant: Yield Engineering Systems, Inc., Fremont, CA (US)

(72) Inventors: Venugopal Govindarajulu, Lehi, UT (US); M Ziaul Karim, San Jose, CA (US); Coby Tao, Chandler, AZ (US)

(73) Assignee: Yield Engineering Systems, Inc., Fremont, CA (US)

(21) Appl. No.: 18/373,394

(22) Filed: Sep. 27, 2023

(51) Int. Cl. H01L 21/67; H01L 21/3213

(52) U.S. Cl. CPC H01L 21/67253; H01L 21/32134; H01L 21/67086; H01L 21/67248

(57) ABSTRACT

A system and a method of wet processing includes receiving real-time signals indicative of one or more of a pH, a temperature, and an electrical conductivity of a liquid chemical in a wet processing tank, and determining values of one or more of a composition, a flow rate, and the temperature of the liquid chemical that will improve or maintain an etch rate of the liquid chemical in the wet processing tank. One or more of the composition, the flow rate, and the temperature of the liquid chemical in the wet processing tank may then be adjusted to the determined values.

### TECHNICAL FIELD

The present disclosure relates to a wet processing system with automatic process control.

### BACKGROUND

Wet processing in the context of semiconductor manufacturing refers to a set of chemical processes that involve the use of liquid chemicals or solutions to manipulate the surface properties of semiconductor substrates (wafers, panels, etc.). These processes are used to clean, etch, and modify the semiconductor materials to create the intricate patterns and structures needed for the fabrication of integrated circuits (ICs) and other semiconductor devices. Wet processing is a critical step in semiconductor manufacturing. A typical wet processing system is a multi-tank system that sequentially processes substrates through multiple wet processing tanks. A wet processing tank (or bath) is a container designed to hold a liquid chemical used in the process. For example, during substrate cleaning, wet processing tanks are used to immerse the substrates in specialized cleaning solutions, and during etching, the substrates are immersed in a wet processing tank containing a suitable etchant. During each of these processes, the composition of the liquid chemical in the tank changes as the process progresses. Therefore, the speed or rate of progress of the process changes over time as the process continues. For example, during etching, the composition of the liquid etchant continues to change as etching progresses and this decreases the rate of etching. To account for these changes, precise control of the process conditions (e.g., the composition, temperature, etc. of the chemical solution, etc.) is important for efficient processing. This becomes even more important in a high volume manufacturing environment where multiple substrates are simultaneously processed in a wet processing tank. Conventional wet processing systems used in high volume manufacturing are manually controlled. For example, the dosing of the chemical bath and etching time are determined with manual calculations and etch rates measured from test substrates. This may lead to increased defects or quality-related issues and decreased efficiency. The systems and methods of the current disclosure may alleviate at least some of these deficiencies.

### SUMMARY

Several embodiments of systems and methods for wet processing a semiconductor substrate are disclosed. It is to be understood that both the foregoing general description and the following detailed description are exemplary and explanatory only. As such, the scope of the disclosure is not limited solely to the disclosed embodiments. Instead, it is intended to cover such alternatives, modifications and equivalents within the spirit and scope of the disclosed embodiments. Persons skilled in the art would understand how various changes, substitutions and alterations can be made to the disclosed embodiments without departing from the spirit and scope of the disclosure.

In one embodiment, a wet processing system is disclosed. The wet processing system comprises a wet processing tank configured to contain a liquid chemical and one or more substrates. The liquid chemical may be configured to subject the one or more substrates to a process. The wet processing system may also include a dosing unit configured to receive the liquid chemical from the wet processing tank and discharge a modified supply of the received liquid chemical into the wet processing tank. A controller may be configured to receive real-time signals indicative of one or more parameters that are indicative of health of the liquid chemical in the wet processing tank with respect to the process that the one or more substrates are being subjected to in the wet processing tank, and determine values of one or more of a composition, flow rate, and temperature of the liquid chemical that will improve or maintain the process that the one or more substrates are being subjected to in the wet processing tank. The controller may also be configured to adjust one or more of the composition, the flow rate, and the temperature of the modified supply of the liquid chemical discharged into the wet processing tank to match the determined values.

In another embodiment, a wet processing system is disclosed. The wet processing system may comprise a wet processing tank configured to contain a liquid chemical and one or more substrates. The liquid chemical may be configured to etch the one or more substrates. The wet processing system may also comprise a dosing unit configured to receive the liquid chemical from the wet processing tank and discharge a modified supply of the received liquid chemical into the wet processing tank. The wet processing system may further comprise a controller configured to continuously receive real-time signals indicative of one or more of a pH, temperature, and electrical conductivity of the liquid chemical in the wet processing tank, determine values of one or more of a composition, flow rate, and temperature of the liquid chemical that will improve or maintain an etch rate of the one or more substrates in the wet processing tank, and adjust one or more of the composition, the flow rate, and the temperature of the modified supply of the liquid chemical discharged into the wet processing tank to match the determined values.

In a further embodiment, a method of wet processing one or more substrates in a wet processing tank is disclosed. The method may include positioning the one or more substrates in a liquid chemical in the wet processing tank, receiving at a controller real-time signals indicative of one or more of a pH, temperature, and electrical conductivity of the liquid chemical in the wet processing tank. The method may also include determining using the controller values of one or more of a composition, flow rate, and temperature of the liquid chemical that will improve or maintain an etch rate of the one or more substrates in the wet processing tank. The method may further include adjusting one or more of the composition, the flow rate, and the temperature of the liquid chemical directed into the wet processing tank to match the determined values.

### BRIEF DESCRIPTION OF THE DRAWINGS

The accompanying drawings, which are incorporated in and constitute a part of this disclosure, illustrate simplified schematic representations of exemplary embodiments. Together with the description, these figures are used to explain the disclosed principles. In these drawings, where appropriate, reference numerals illustrating like structures, components, materials, and/or elements in different figures are labeled similarly. It should be noted that the figures are only simplified schematics of exemplary embodiments and there can be many features and variations not shown in these figures. It is understood that various combinations of the structures, components, and/or elements, other than those specifically shown, are contemplated and are within the scope of the present disclosure. Specifically, the scope of the current disclosure is defined by the claims and not by the specific embodiments illustrated in the figures.

For simplicity and clarity of illustration, the figures depict the general structure of the various described embodiments. Details of well-known components or features may be omitted to avoid obscuring other features, since these omitted features are well-known to those of ordinary skill in the art. Further, elements in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing proportional relationships between features in a figure. Additionally, even if it is not specifically mentioned, aspects described with reference to one embodiment or figure may also be applicable to, and may be used with, other embodiments or figures.

FIG. 1 is a simplified schematic illustration of an exemplary wet processing system of the current disclosure;

FIGS. 2A and 2B are representative graphs that indicate the dependence of etch rate on parameters of the etchant;

FIG. 2C is a flow chart of an exemplary process of using a disclosed wet processing system.

### DETAILED DESCRIPTION

All relative terms such as “about,” “substantially,” “approximately,” etc., indicate a possible variation of ±10% (unless noted otherwise or another variation is specified). For example, a feature disclosed as being about “t” units long (wide, thick, etc.) may vary in length from (t−0.1t) to (t+0.1t) units. Similarly, a temperature within a range of about 100-150° C. can be any temperature between (100−10%) and (150+10%). In some cases, the specification also provides context to some of the relative terms used. For example, a structure described as being substantially linear or substantially planar may deviate slightly (e.g., 10% variation in diameter at various locations, etc.) from being perfectly circular or cylindrical. Further, a range described as varying from, or between, 5 to 10 (5-10), includes the endpoints (i.e., 5 and 10).

Unless otherwise defined, all terms of art, notations, and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in the references that are incorporated by reference. None of the references described or referenced herein is admitted as prior art to the current disclosure.

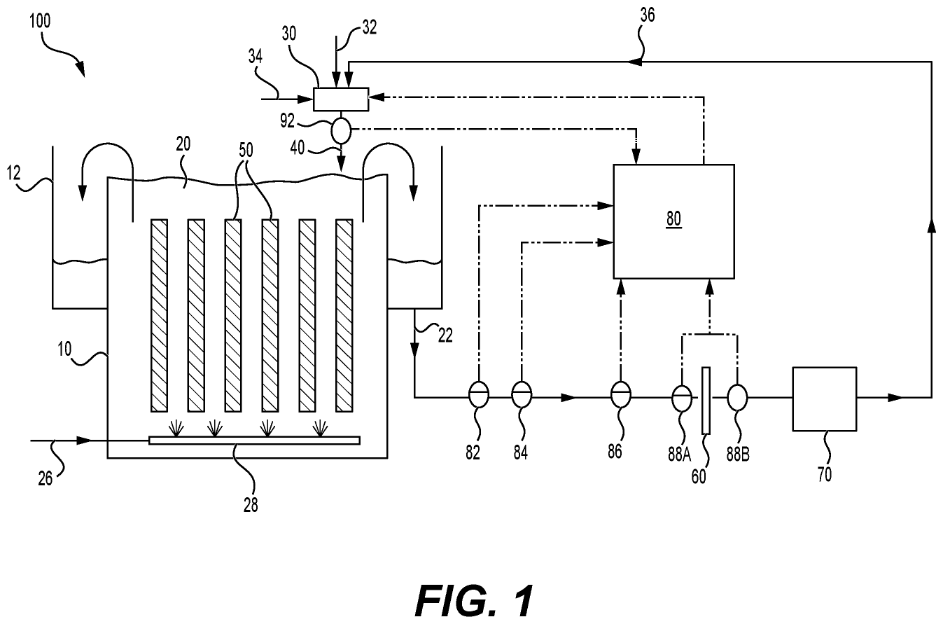

FIG. 1 is a simplified schematic illustration of an exemplary wet processing system 100 (system 100) consistent with the current disclosure. System 100 includes a bath or a tank 10 containing a liquid chemical composition (or chemical 20). Any type and composition of liquid may be used as chemical 20. In general, the type of chemical 20 may depend on the application. For example, if system 100 is used for cleaning substrates 50, a solution that is suitable for cleaning may be used as chemical 20. Similarly, if system 100 is used for etching, a solution suitable for etching may be used as chemical 20. Non-limiting examples of chemical 20 used in different applications include: various concentrations (e.g., 30%, 50%, etc.) of Sodium Hydroxide (NaOH), various concentrations of Potassium Hydroxide (KOH), various concentrations of Hydrogen Fluoride (HF); various concentrations of Sulfuric Acid (H₂SO₄); and various concentrations of Citric Acid. Tank 10 may, in general, include any volume (e.g., 10-80 gallons, etc.) of chemical 20.

As used herein, the term “substrate” broadly refers to any component or part on which electronic devices and integrated circuits are fabricated. For example, a substrate may include a semiconductor wafer having opposite flat surfaces, a glass panel, a printed circuit board (PCB), an organic substrate, an electronic package that may support one or more integrated circuit (IC) chips or devices thereon. In general, the substrate may be made of any material and may have any shape (circular, rectangular, square, etc.), size, and thickness. In some embodiments, the substrate may be a square or rectangular glass panel. However, this is only exemplary, and in general, any type and shape of substrate may be processed in tank 10 of system 100.

Typically, multiple substrates 50 may be disposed (or immersed) in the chemical 20 in tank 10. In general, any number (e.g., 1-50) of substrates 50 may be disposed in tank 10. In some embodiments, multiple substrates 50 (e.g., 12-25) may be disposed in tank such that the facing surfaces of adjacent substrates are spaced apart and substantially parallel to each other. The gap between the substrates 50 will enable the chemical 20 to flow between the substrates 50 and treat (e.g., clean, etch, etc.) the opposing surfaces of the substrates 50. Although not shown in FIG. 1, in some embodiments, the multiple substrates 50 may be supported by a carrier in the tank 10.

In some embodiments, chemical 20, that may be dispensed from an inlet 40 into the tank 10, may fill the tank 10 and overflow into a weir 12 formed around the edge of the tank 10. The chemical 20 may then flow out of the weir 12 through an outlet 22 and be treated (e.g., filtered, heated, etc.) before being directed back into the tank. In some embodiments, a filter 60 and a heater 70 may be provided in system 100 to filter and heat the chemical 20 recirculated back into tank 10. As the chemical 20 flows up in tank 10 (e.g., between the substrates 50), it treats (e.g., cleans, etches, etc.) the substrate surfaces and undergoes a change in composition. In some embodiments, as illustrated in FIG. 1, a bubbler tuber 28 may be provided a release a gas (nitrogen, air, etc.) into the chemical 20 in tank 10 and generate turbulence. It accomplishes this by releasing the gas into the liquid to create bubbles that rise to the surface. As the bubbles rise, they disturb the surrounding chemical 20, causing agitation and mixing.

The type of chemical 20 used depends on the application for which tank 10 is employed. For example, if the tank 10 is used for etching substrates 50 (or materials deposited on the substrates 50), a suitable etchant may be used as the chemical 20. In some such embodiments, the primary chemical reactions between the etchant and the material being etched and the reaction byproducts may lead to changes in the concentration of the chemical 20 as etching proceeds. For example, in metal etching, if the etchant is an acid, it may react with the metal to form metal ions and other compounds. Byproducts from the primary etching reaction may further react with the etchant or other components in the solution and lead to further changes in the composition of the chemical 20. Additionally or alternatively, in some embodiments, evaporation of water from the chemical 20 may lead to a change in the composition of the chemical 20. In some embodiments temperature changes in the tank 10 may result in changes in the composition of chemical 20. The pH (e.g., acidity or alkalinity) of the chemical 20 and its electrical conductivity may also change due to reactions between the chemical 20 and the material being etched, as well as any other substances present. For consistent and reliable performance of the process being carried out in tank 10 (e.g., cleaning, etching, etc.), it is important to monitor and maintain the composition of the chemical 20 (e.g., within acceptable limits) in tank 10.

In some embodiments of the current disclosure, one or more parameters such as, for example, temperature (T), pH (P), electrical conductivity (C), flow rate (F), etc., of the chemical 20 in tank 10 may be monitored. In general, any parameter that is indicative of the health of the chemical 20 for the process being carried out in tank 10 (e.g., etching, cleaning, etc.) may be monitored. For example, when chemical 20 is used to etch the substrates 50 (or materials deposited on the substrate) in tank 10, parameters that are indicative of etching capability (e.g., etch rate, uniformity of etching, etc.) of the chemical 20 may be monitored. And based on the monitored parameters, characteristics of the chemical 20 fed into, or redirected back into, tank 10 may be adjusted (e.g., by replenishment or replacement of the chemical 20) to maintain the desired chemical properties of the chemical 20. To monitor the condition of the chemical 20 in tank 10, a variety of sensors may be provided. For example, in some embodiments, sensors such as, for example, temperature sensor 82, pH sensor 84, conductivity sensor 86, flow meter 92, and pressure sensors 88A, 88B may be provided to measure (or detect) the temperature (T), pH (P), thermal conductivity (C), flow rate (F), and differential pressure (of the chemical 20 across the filter 60) of the chemical 20. It should be noted that, alternative to or in addition to the above-mentioned sensors, other sensors may also be provided. Any commercially available sensor may be provided to measure the above-mentioned or other parameters of the chemical 20 in tank 10. It should be noted that, although these sensors are illustrated in FIG. 1 as being located in the recirculation pathway of the chemical 20 outside tank 10, this is only exemplary. In general, these sensors may be positioned at any location that is suitable to measure the conditions of the chemical 20 in tank 10. For example, in some embodiments, some or all of these sensors may be disposed within tank 10. In some embodiments, additional sensors (e.g., specific gravity sensor, sensor to determine dissolved metal concentration, sensor to detect contaminant level and/or byproduct concentrations, sensor to detect light exposure, etc.) may also be provided to measure other parameters that may be indicative of, or affect, the health of the process (e.g., reactions) occurring in tank 10 (e.g., cleaning, etching, etc.).

System 100 may also include a controller 80 that manages and regulates the operation of system 100 to achieve desired processing outcomes in tank 10. Controller 80 may be a component or a system (e.g., made of multiple components) that may receive input from different sensors in system 100 to monitor process conditions in the tank 10 and manage factors such as, for example, chemical concentration, temperature, flow rates, and other parameters of the chemical 20 entering tank 10 (e.g., from inlet 40) to ensure accurate and consistent processing of the substrates 50 in tank 10. Generally, controller 80 may constitute any physical device or group of devices having electric circuitry that performs a logic operation based on one or more inputs. For example, controller 80 may include one or more integrated circuit (IC) based processors, such as, for example, microprocessors, application-specific integrated circuit (ASIC), microchips, microcontrollers, central processing unit (CPU), graphics processing unit (GPU), digital signal processor (DSP), field-programmable gate array (FPGA), or other circuits suitable for executing instructions or performing logic operations. The instructions executed by this processor(s) may, for example, be pre-loaded into a memory integrated with or embedded into the controller or may be stored in a separate memory accessible to controller 80. The memory may include a Random Access Memory (RAM), a Read-Only Memory (ROM), a hard disk, an optical disk, a magnetic medium, a flash memory, other permanent, fixed, or volatile memory, or any other mechanism capable of storing instructions and data.

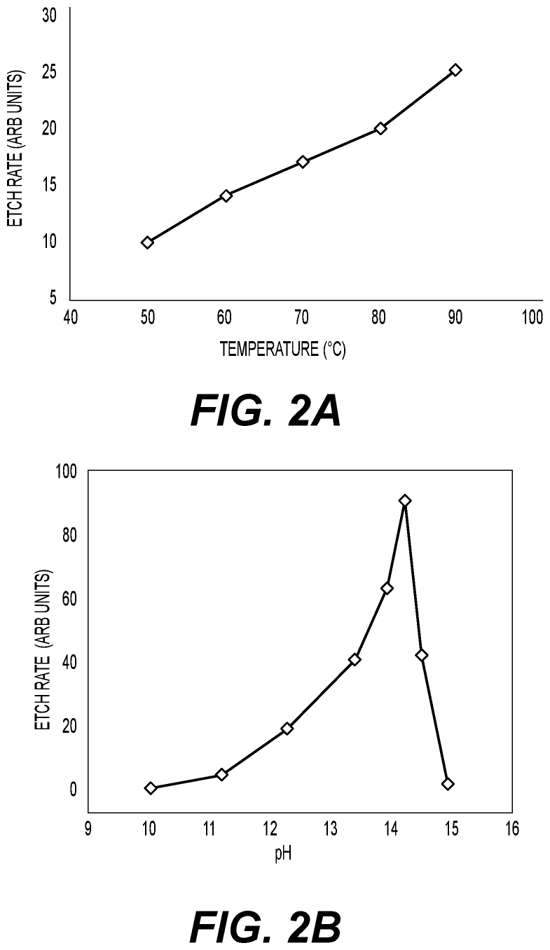

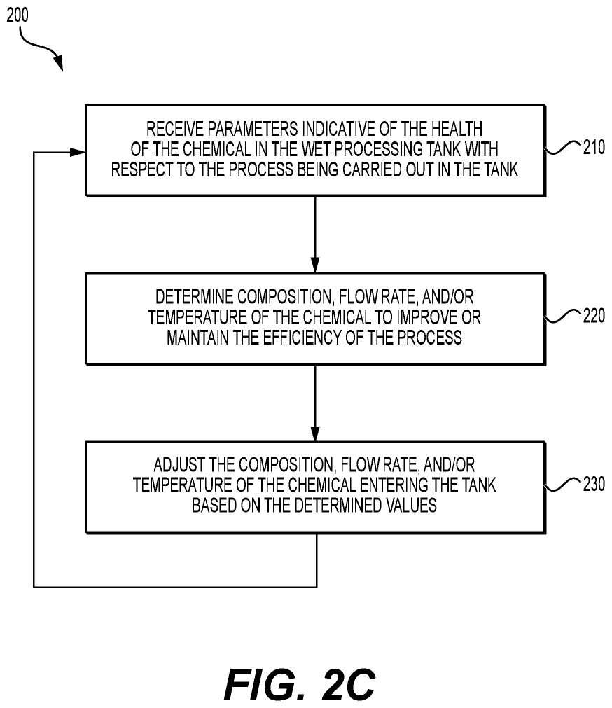

Signals from the sensors (e.g., sensors 82, 84, 68, 88A, 88B, 92, etc.) of system 100 that indicate the parameters of the chemical 20 in tank 10 may be directed to controller 80. Controller 80 may also include, or have access to, data indicative of the effect of one or more of the monitored parameters on the process occurring in tank 10. In some embodiments, such data may be stored in a memory of, or accessible to (e.g., operatively connected to), controller 80. As an example, when tank 10 is used for etching a metal layer deposited on substrates 50, the parameters (temperature, pH, electrical conductivity, etc.) of the chemical 20 in tank 10 (e.g., the etchant) may have a significant effect on the etching process (e.g., etching rate, etc.). For example, higher temperatures generally increase the rate of chemical reactions. Therefore, at elevated temperatures, the etchant may react more rapidly with the metal surface and lead to a higher etching rate. Similarly, pH directly affects the ionization state of the etchant solution. Different pH levels can alter the reactivity of the etchant with the metal surface. For example, in an acidic solution, metal ions may be more readily formed, leading to a faster etching rate. Conductivity is a measure of the solution's ability to carry an electrical current, which is primarily due to the presence of ions. Higher conductivity may indicate a higher concentration of ions in the solution which can enhance the transport of the etchant species to the metal surface, potentially leading to an increased etching rate. In some embodiments, high differential pressure across the filter 60 may indicate high particulate contamination which may lead to process variations and reduced yield, and potential damage to equipment. In some embodiments, data indicative of the effect of different parameters of the chemical 20 on the etching rate (or other process-related outcomes) may be obtained apriori (e.g., experimentally, from literature, etc.) and stored (e.g., in a database) in a memory accessible to controller 80. FIGS. 2A and 2B illustrate the effect of etch rate on etchant temperature and pH for an exemplary chemical 20 that may be used in tank 10. In some embodiments, data similar to this shown in FIGS. 2A and 2B may be experimentally obtained and stored in a memory accessible to controller 80. Controller 80 may have access to similar data indicative of the effect of parameters of different chemicals 20 (e.g., NaOH solution, KoH solution, etc.) on different process outcomes (e.g., speed of cleaning, quality of cleaning, etching rate, quality of etching, etc.).

When tank 10 is used, for example, for etching, the etch rate may reduce over time due to the loss of active ingredients of the chemical 20 in tank 10 and the influence of by-products from the etching reaction. In embodiments of the current disclosure, based on the received signals from the sensors (e.g., data indicative of one or more parameters of chemical 20 in tank 10 from the sensors 82, 84, 68, 88A, 88B, 92, etc.) and the stored data (e.g., data indicative of the effect of the parameters on the process occurring in tank 10), controller 80 may determine and adjust the characteristics (e.g., composition, temperature, flow rate, etc.) of the chemical 20 entering the tank 10 (e.g., via inlet 40) to keep the etch rate at the desired level throughout the etching process. For example, the controller 80 may continuously (or periodically) determine the amount (e.g., volume) of used chemical 20 to remove (or bleed) from the tank 10 and the amount of fresh chemical to add into the tank 10 to keep the etch rate (or other process outcome) at the desired level. In some embodiments, controller 80 may activate a dosing unit 30 of system 100 to direct a desired composition, flow rate and/or temperature (as predicted by controller 80) of the chemical entering the tank 10 to maintain the etch rate in the tank 10 at a consistent level. In an exemplary etching application, thin glass panels may be etched in tank 10 using a 50% Sodium Hydroxide (NaOH) solution. Based on the detected parameters (e.g., pH, conductivity) of the NaOH solution in the tank 10, controller 80 may determine, for example, the dosing, temperature, and flow rate of NaOH solution to direct into the tank 10 via input 40. With reference to FIG. 1, in some exemplary embodiments, the controller 80 may adjust the dosing by removing a determined amount of the used NaOH solution returning to tank 10 via flow 36, directing a determined amount of fresh NaOH into tank 10 via flow 32, and directing a determined amount of DI water into tank 10 via flow 34. By varying the ratio of NaOH to water entering the tank 10, the concentration of the active ingredient in the chemical 20 in tank 10 may be varied. The flow rate and temperature of the NaOH solution entering the tank 10 may be adjusted by activating valves and heaters of system 100.

Thus, in some embodiments of the current disclosure, multiple gallons of an etch chemical 20 in a tank 10 is kept in a consistent etch rate regime by an automatic process controller 80 that receives inputs regarding the condition of the etch chemical in the tank 10. When the etch rate of the chemical 20 reduces over time (e.g., due to the loss of active chemistry and the influence of by-products from the etching process), fresh chemistry is dosed into the tank 10 while some amount (e.g., an equal amount) of the used chemical is removed from the tank 10 (e.g., to account for the added volume). In some embodiments, the conductivity and pH (and/or other parameters indicative of the health of the chemical with regard to etching) of the chemical in the tank 10 may be continuously fed back to the controller 80 to determine the dosing, temperature, and flow of the fresh chemical 20 into the tank 10. In some embodiments, the controller 80 may apply data processing techniques to the received data to continuously monitor the progress of the etching process.

FIG. 2C is a flow chart of an exemplary process 200 of using a wet processing system 100 of the current disclosure. As a process (e.g., etching, cleaning, etc.) is being carried out in the wet processing tank 10 of the system 100, the controller 80 may receive signals indicative of the health of the chemical with respect to the process (step 210). For example, when a substrate is being etched in the tank 10, the controller 80 may receive signals (e.g., real-time signals) of parameters that are indicative of the current etch rate (or another measurable outcome of the etching process) in the tank 10. The controller 80 may then determine the composition, flow rate, and/or the temperature of the chemical to improve or maintain the efficiency of the process (step 220). Continuing with the etching example, in this step, the controller may determine the composition, flow rate, and/or the temperature of the chemical to keep the etch rate in the tank constant (e.g., as it was at the start of the process). The controller 80 may then adjust the composition, flow rate, and/or the temperature of the chemical entering the tank 10 based on the determined values in step 220 (step 230). In the etching example, the controller 80 may adjust the composition, flow rate, and/or the temperature of the chemical entering the tank 10 to those determined by the controller 80 to keep the etch rate a constant. The controller 80 may continue to receive signals indicative of the health of the chemical in the tank and adjust the composition, flow rate, and/or the temperature of the chemical entering the tank to improve or maintain the outcome of the process.

The process described above is merely exemplary and many variations are possible. For example, the order of the steps may be different, some of the illustrated steps may be eliminated or combined, etc. A person of ordinary skill in the art would recognize other possible variations.

What is claimed is:

1. A wet processing system, comprising:
a wet processing tank configured to contain a liquid chemical and one or more substrates, wherein the liquid chemical is configured to subject the one or more substrates to a process;
a dosing unit configured to receive the liquid chemical from the wet processing tank and discharge a modified supply of the received liquid chemical into the wet processing tank; and
a controller configured to,
receive real-time signals indicative of one or more parameters that are indicative of health of the liquid chemical in the wet processing tank with respect to the process that the one or more substrates are being subjected to in the wet processing tank,
determine values of one or more of a composition, flow rate, and temperature of the liquid chemical that will improve or maintain the process that the one or more substrates are being subjected to in the wet processing tank; and
adjust one or more of the composition, the flow rate, and the temperature of the modified supply of the liquid chemical discharged into the wet processing tank to match the determined values.

2. The system of claim 1, wherein the dosing unit is configured to generate the modified supply of the liquid chemical by mixing at least a fresh supply of the liquid chemical with the liquid chemical received from the wet processing tank.

3. The system of claim 1, wherein the received real-time signals include signals indicative of one or more of pH, temperature, and electrical conductivity of the liquid chemical in the wet processing tank.

4. The system of claim 1, wherein the liquid chemical is configured to subject the one or more substrates in the wet processing tank to an etching process.

5. The system of claim 1, further including a temperature sensor configured to measure a temperature of the liquid chemical in the wet processing tank, a pH sensor configured to measure a pH of the liquid chemical in the wet processing tank, and a conductivity sensor configured to measure an electrical conductivity of the liquid chemical in the wet processing tank.

6. The system of claim 1, further including a filter configured to filter the liquid chemical discharged from the wet processing tank.

7. The system of claim 6, further including one or more pressure sensors configured to measure a difference in pressure of the liquid chemical across the filter.

8. The system of claim 6, further including a heater configured to heat the liquid chemical discharged from the wet processing tank.

9. A wet processing system, comprising:
a wet processing tank configured to contain a liquid chemical and one or more substrates, wherein the liquid chemical is configured to etch the one or more substrates;
a dosing unit configured to receive the liquid chemical from the wet processing tank and discharge a modified supply of the received liquid chemical into the wet processing tank; and
a controller configured to continuously,
receive real-time signals indicative of one or more of a pH, temperature, and electrical conductivity of the liquid chemical in the wet processing tank,
determine values of one or more of a composition, flow rate, and temperature of the liquid chemical that will improve or maintain an etch rate of the one or more substrates in the wet processing tank; and
adjust one or more of the composition, the flow rate, and the temperature of the modified supply of the liquid chemical discharged into the wet processing tank to match the determined values.

10. The system of claim 9, wherein the liquid chemical is one of a sodium hydroxide solution or a potassium hydroxide solution.

11. The system of claim 9, wherein the controller is configured to continuously receive real-time signals indicative of the pH, the temperature, and the electrical conductivity of the liquid chemical in the wet processing tank.

12. The system of claim 9, further including a temperature sensor configured to measure a temperature of the liquid chemical in the wet processing tank, a pH sensor configured to measure a pH of the liquid chemical in the wet processing tank, and a conductivity sensor configured to measure an electrical conductivity of the liquid chemical in the wet processing tank.

13. The system of claim 9, further including a filter configured to filter the liquid chemical discharged from the wet processing tank and one or more pressure sensors configured to measure a difference in pressure of the liquid chemical across the filter.

14. The system of claim 13, further including a heater configured to heat the liquid chemical discharged from the wet processing tank.

15. A method of wet processing one or more substrates in a wet processing tank, comprising:
positioning the one or more substrates in a liquid chemical in the wet processing tank;
receiving, at a controller, real-time signals indicative of one or more of a pH, temperature, and electrical conductivity of the liquid chemical in the wet processing tank;
determining, using the controller, values of one or more of a composition, flow rate, and temperature of the liquid chemical that will improve or maintain an etch rate of the one or more substrates in the wet processing tank; and
adjusting one or more of the composition, the flow rate, and the temperature of the liquid chemical directed into the wet processing tank to match the determined values.

16. The method of claim 15, wherein positioning the one or more substrates in the liquid chemical in the wet processing tank includes positioning one or more glass panels in one of a sodium hydroxide solution or potassium hydroxide solution in the wet processing tank.

17. The method of claim 15, wherein receiving real-time signals includes continuously receiving real-time signals indicative of the pH, the temperature, and the electrical conductivity of the liquid chemical in the wet processing tank.

18. The method of claim 17, wherein adjusting one or more of the composition, the flow rate, and the temperature of the liquid chemical includes continuously adjusting one or more of the composition, the flow rate, and the temperature of the liquid chemical.
